(19) United States
(12) Patent Application Publication
(10) Pub. No.: US 2011/0088755 A1
(43) Pub. Date: Apr. 21, 2011

(54) MOBILE SOLAR POWER GENERATOR

(76) Inventor: Robert SUN, Tamuning, GU (US)

(21) Appl. No.: 12/580,020

(22) Filed: Oct. 15, 2009

(51) Int. Cl. H01L 31/058

(52) U.S. Cl. 136/248

(57) ABSTRACT

A mobile solar power generator is disclosed. The mobile solar power generator includes a plurality of solar energy collecting plates, a thermoelectric conversion unit, and a power distribution unit. The solar energy collecting plates are disposed at a top and/or a lateral side of the thermoelectric conversion unit for collecting thermal energy provided by the sun. The thermoelectric conversion unit is adapted for utilizing the collected thermal energy to vaporize a liquid into a vapor, and generating electric power with the vapor. The liquid has a relatively low boiling point. The power distribution unit is coupled to the thermoelectric conversion unit, for providing the electric power generated by the thermoelectric conversion unit to drive an external electric appliance.

### BACKGROUND OF THE INVENTION

1. Field of the Invention

The present invention relates generally to a mobile solar power generator, and more particularly, to a solar power generator which is small, light, and mobile. Such a mobile solar power generator can be operated with fewer limitations in such as place of use, cloudy day, or illumination angle of the sun.

2. The Prior Arts

Currently, environmental protection is being paid more attention. Accordingly, renewable energies are encouraged to develop for sustainably maintaining the environment. As a result, the solar power industry has presented its great potential. Generally, the solar energy can be utilized with two approaches; one is photoelectric conversion type and the other is thermal conversion type. Typically, the photoelectric conversion type is to use a solar cell to convert the solar energy into electric energy for storage. However, solar cells are usually very expensive, while the photoelectric conversion efficiency is still restricted by the related techniques. As to the thermal conversion type, the solar energy is typically utilized by employing a solar power collecting plate for collecting the solar thermal energy, e.g., household solar water heater. Unfortunately, such a heater appliance is usually large and heavy, and inconvenient to move, and therefore the application of the thermal conversion type is much restricted by some factors, such as place of use, cloudy day, or illumination angle of the sun.

### SUMMARY OF THE INVENTION

A primary objective of the present invention is to provide a mobile solar power generator. The mobile solar power generator includes at least one solar energy collecting plate, a thermoelectric conversion unit, and a power distribution unit. The at least one solar energy collecting plate is disposed at a top and/or a lateral side of the thermoelectric conversion unit for collecting thermal energy provided by the sun. The thermoelectric conversion unit is adapted for utilizing the collected thermal energy to vaporize a liquid into a vapor, and generating electric power with the vapor. The liquid has a relatively low boiling point. The power distribution unit is coupled to the thermoelectric conversion unit, for providing the electric power generated by the thermoelectric conversion unit to drive an external electric appliance.

The present invention is featured in that the liquid having a low boiling point is vaporized into a high pressure vapor for generating electric power. The solar power generator is light, small, and mobile, and therefore is not restricted by some factors such as place of use, cloudy day, or illumination angle of the sun.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a schematic diagram illustrating the structure of a mobile solar power generator according to an embodiment of the present invention; and

FIG. 2 is a schematic diagram illustrating the structure of a thermoelectric conversion unit of the mobile solar power generator according to an embodiment of the present invention.

### DETAILED DESCRIPTION OF THE PREFERRED EMBODIMENT

The accompanying drawings are included to provide a further understanding of the present invention, and are incorporated in and constitute a part of this specification. The drawings illustrate embodiments of the present invention and, together with the description, serve to explain the principles of the present invention.

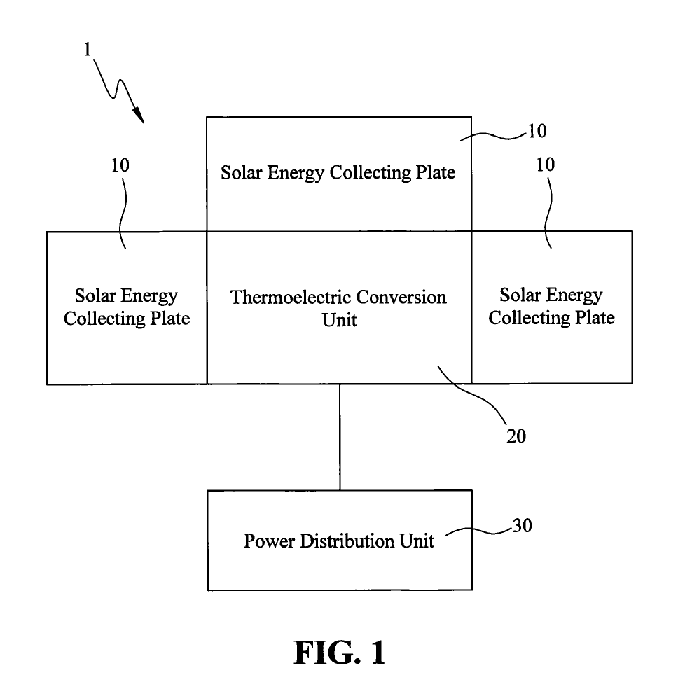

FIG. 1 is a schematic diagram illustrating the structure of a mobile solar power generator according to an embodiment of the present invention. Referring to FIG. 1, there is shown a mobile solar power generator 1 including a plurality of solar energy collecting plates 10, a thermoelectric conversion unit 20, and a power distribution unit 30. The solar energy collecting plates 10 are disposed with a specific arrangement on a top and two lateral sides of the thermoelectric conversion unit 20, for collecting thermal energy emitted from the sun. The thermoelectric conversion unit 20 is adapted for utilizing the collected thermal energy to vaporize a liquid into a vapor, and generating electric power with the vapor. The liquid has a relatively low boiling point. The power distribution unit 30 is coupled to the thermoelectric conversion unit 20, for providing the electric power generated by the thermoelectric conversion unit 20 to drive an external electric appliance.

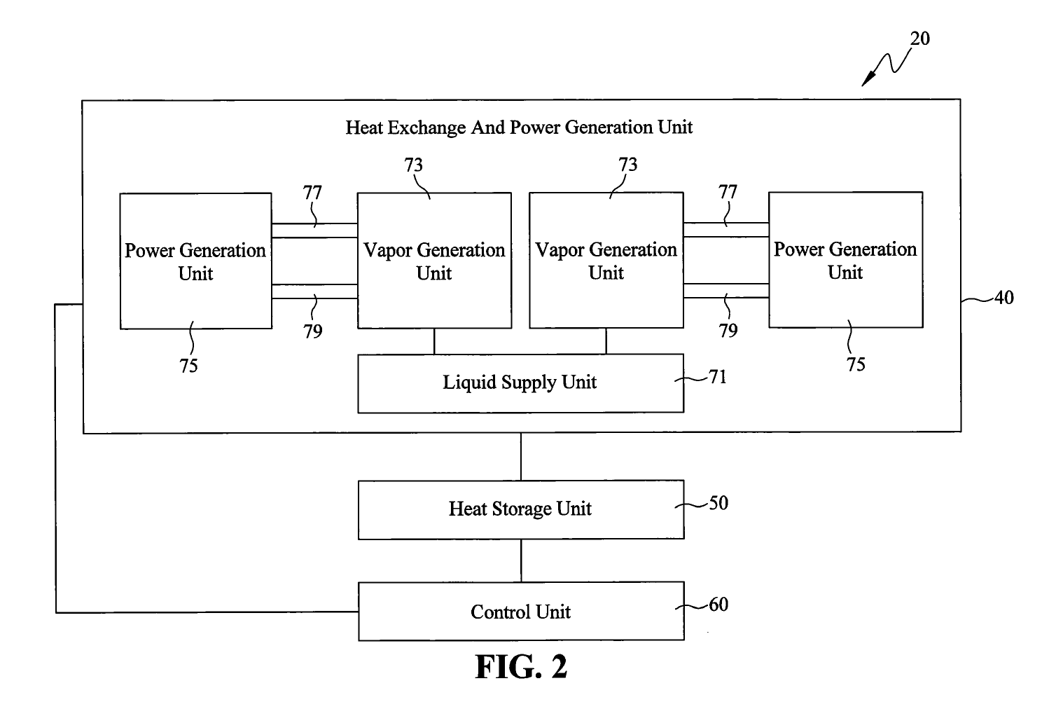

FIG. 2 is a schematic diagram illustrating the structure of the thermoelectric conversion unit 20 of the mobile solar power generator 1 according to an embodiment of the present invention. Referring to FIG. 2, the thermoelectric conversion unit 20 includes a heat exchange and power generation unit 40, a heat storage unit 50, and a control unit 60. The heat exchange and power generation unit 40 is coupled to the solar energy collecting plates 10, the heat storage unit 50, and the control unit 60. The heat exchange and power generation unit 40 utilizes the collected thermal energy to vaporize a liquid into a vapor, and generating electric power with the vapor. The electric power is then transferred to the power distribution unit 30, and is provided to the external electric appliance whereby. The control unit 60 is electrically connected to the heat storage unit 50, and the heat exchange and power generation unit 40. When the thermal energy collected by the solar energy collecting plates 10 is more than the demanded, the surplus thermal energy is stored in the heat storage unit 50, and when the thermal energy collected by the solar energy collecting plates 10 is insufficient for vaporizing the liquid, the previously stored thermal energy is released from the heat storage unit 50 and provided for the heat exchange and power generation unit 40 for power generation operation.

The heat exchange and power generation unit 40 includes a liquid supplying unit 71, at least one vapor generation unit 73, and at least one power generation unit 75. The liquid supplying unit 71 is adapted for supplying a liquid to the vapor generation units 73. The vapor generation units 73 vaporize the liquid into a high pressure vapor with the thermal energy collected by the solar energy collecting plates 10. Via an inlet pipe 77, the high pressure vapor is guided into the power generation unit 75 for driving a power generator (not shown in the drawing) of the power generation unit 75 to generate electric power. After driving the power generator for generating the electric power, the high pressure vapor becomes a low pressure vapor, and is then recycled via a recycling pipe 79 back to the vapor generation unit 73 for recycling use.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A mobile solar power generator, comprising:
a plurality of solar energy collecting plates for collecting a thermal energy emitted from the sun;
a thermoelectric conversion unit, adapted for vaporizing a liquid into a high pressure vapor with the thermal energy collected by the solar energy collecting plates, and generating electric power with the high pressure vapor; and
a power distribution unit, coupled to the thermoelectric conversion unit, for providing the electric power generated by the thermoelectric conversion unit to an external electric appliance,
wherein the solar energy collecting plates are disposed on a top and at least one lateral side of the thermoelectric conversion unit, and the liquid is characterized with a relatively low boiling point.

2. The mobile solar power generator according to claim 1, wherein the thermoelectric conversion unit comprises:
a heat exchange and power generation unit, coupled to the solar energy collecting plates and the power distribution unit, for utilizing the thermal energy collected by the solar energy collecting plates to vaporize the liquid into the high pressure vapor, and generating the electric power with the high pressure vapor, and then transferring the generated electric power to the power distribution unit;
a heat storage unit, coupled to the heat exchange and power generation unit, for storing the thermal energy; and
a control unit, coupled with the heat exchange and power generation unit and the heat storage unit,
wherein when the thermal energy collected by the solar energy collecting plates is more than demanded, a surplus part of the thermal energy is stored in the heat storage unit, and when the thermal energy collected by the solar energy collecting plates is insufficient for vaporizing the liquid, the previously stored thermal energy is released from the heat storage unit and provided for the heat exchange and power generation unit for power generation operation.

3. The mobile solar power generator according to claim 2, wherein the heat exchange and power generation unit comprises:
at least one vapor generation unit, adapted for utilizing the thermal energy collected by the solar energy collecting plates to vaporize the liquid into the high pressure vapor;
a liquid supply unit, coupled to the vapor generation unit, for supplying the liquid to the vapor generation units;
at least one power generation unit, coupled with the vapor generation unit, wherein the high pressure vapor is guided via an inlet pipe into the power generation unit for generating the electric power, and after generating the electric power, the high pressure vapor becomes a low pressure vapor, and is then recycled via a recycling pipe back to the vapor generation unit for recycling use.
